(19) United States
(12) Patent Application Publication
(10) Pub. No.: US 2012/0102933 A1
(43) Pub. Date: May 3, 2012

(54) THERMOELECTRIC GENERATOR

(75) Inventors: Madalina Andreea Stefan, Trostberg (DE); Roland Bauer, Offstein (DE)

(73) Assignee: BASF SE, Ludwigshafen (DE)

(21) Appl. No.: 13/281,925

(22) Filed: Oct. 26, 2011

Related U.S. Application Data
(60) Provisional application No. 61/407,035, filed on Oct. 27, 2010.

(51) Int. Cl. F01N 5/02; H01L 35/30

(52) U.S. Cl. 60/320; 136/205; 136/224

(57) ABSTRACT

A thermoelectric generator is described, which comprises at least one thermoelectric module between a hot side, which is connected to a heat source, and a cold side, which is connected to a heat sink, wherein a membrane rests against the cold side of the thermoelectric module, on which membrane a hydraulic pressure is exerted via a pressurized heat transfer fluid lying against the other side of the membrane, with which pressure the thermoelectric module is pressed against the hot side of the thermoelectric generator, and/or wherein a corresponding membrane rests against the hot side of the thermoelectric module.

The invention relates to a thermoelectric generator and a thermoelectric generator unit, which comprises a plurality of thermoelectric generators.

Thermoelectric generators and Peltier arrangements as such have been known for a long time. Semiconductors with p- and n-doping, which are heated on one side and cooled on the other side, transport electrical charges through an external circuit, wherein electrical work may be performed at a load in the circuit. The efficiency of the conversion of heat into electrical energy that is achieved in the process is limited thermodynamically by the Carnot efficiency. Thus, at a temperature of 1000 K on the hot and 400 K on the “cold” side, an efficiency of (1000−400): 1000=60% would be possible. However only efficiencies of up to 6% have been achieved to date.

If, on the other hand, a direct current is applied to such an arrangement, then heat is transported from one side to the other side. Such a Peltier arrangement operates as a heat pump and is therefore suitable for cooling apparatus parts, vehicles or buildings. Heating by way of the Peltier principle is also more favorable than conventional heating, because more heat is always transported than corresponds to the energy equivalent supplied.

At present, thermoelectric generators are used in space probes for generating direct currents, for the cathodic corrosion protection of pipelines, for supplying energy to light and radio buoys, and for operating radios and television sets. The advantages of thermoelectric generators reside in their extreme reliability. For instance, they operate independently of atmospheric conditions such as atmospheric humidity; there is no disturbance-prone mass transfer, only charge transfer; the fuel is combusted continuously, including catalytically without a free flame, whereby only small quantities of CO, NOₓ and uncombusted fuel are released; it is possible to use any fuels from hydrogen through natural gas, gasoline, kerosene, diesel fuel to biologically obtained fuels such as rapeseed oil methyl ester.

Thermoelectric energy conversion thus fits extremely flexibly into future requirements such as hydrogen economy or energy generation from renewable energies.

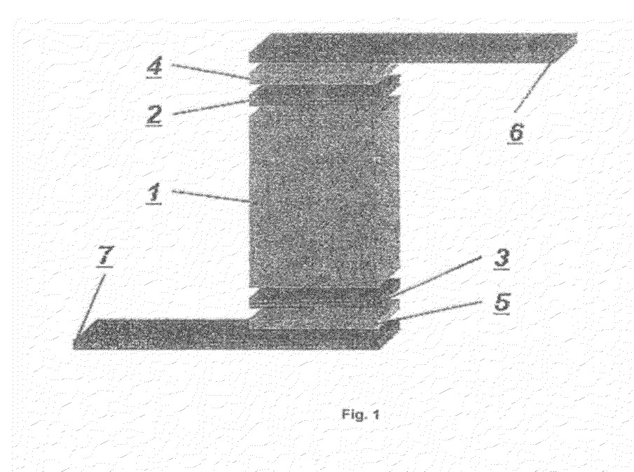

FIG. 1 is a schematic view of a contact in a thermoelectric component.

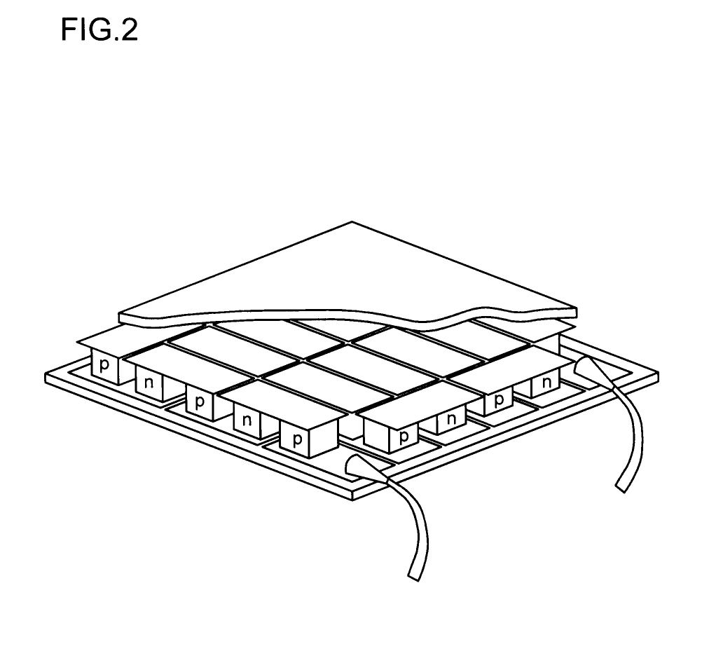

FIG. 2 is a schematic view of a thermoelectric module.

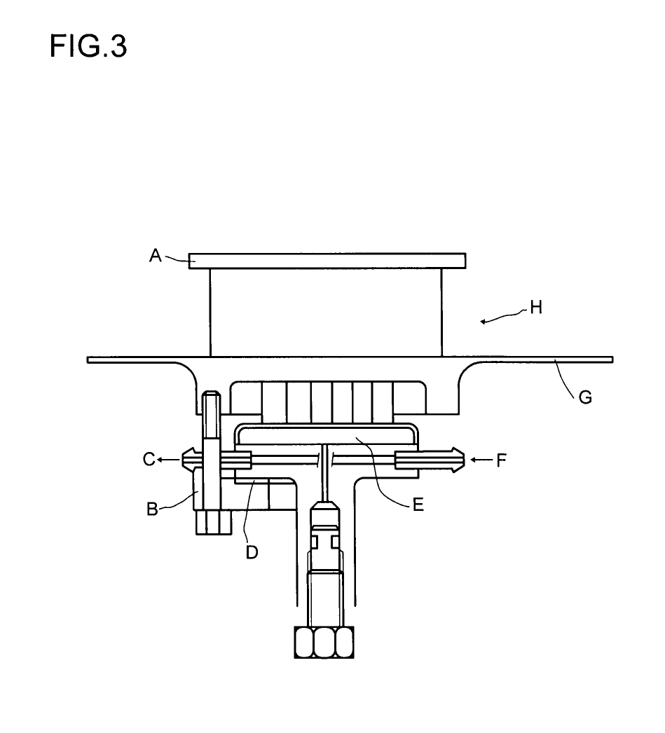

FIG. 3 is a schematic view of an embodiment of a thermoelectric generator.

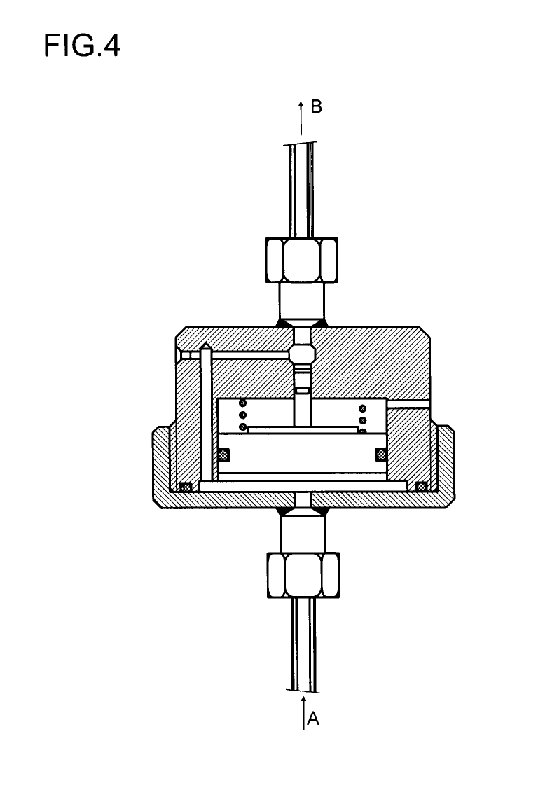

FIG. 4 is a schematic view of an embodiment of a pressure intensifier.

A thermoelectric module consists of p- and n-legs, which are connected electrically in series and thermally in parallel. FIG. 2 shows such a module.

The conventional construction consists of two ceramic plates, between which the individual legs are applied in alternation. Electrically conductive contact is made with every two legs via the end faces. The ceramic plates are not absolutely necessary, however, it merely being necessary for electrical insulation to be present between the contacted legs and the component to which connection is to be made.

In addition to the electrically conductive contacting, various further layers are normally also applied to the actual material, which serve as protective layers or as solder layers. Ultimately, the electrical contact between two legs is established via a metal bridge, however.

An essential element of thermoelectric components is the contacting. Contacting establishes the physical connection between the material at the “heart” of the component (which is responsible for the desired thermoelectric effect of the component) and the “outside world”. In detail, the structure of such a contact is illustrated schematically in FIG. 1.

The thermoelectric material 1 within the component ensures the actual effect of the component. This is a thermoelectric leg. An electric current and a thermal current flow through the material 1 in order that the latter fulfils its purpose in the overall construction.

The material 1 is connected on at least two sides to the supply lines 6 and 7 via the contacts 4 and 5 respectively. In this case, the layers 2 and 3 are intended to symbolize one or more optionally necessary intermediate layers (barrier material, solder, bonding agent or the like) between the material 1 and the contacts 4 and 5. The segments 2/3, 4/5, 6/7 respectively associated with one another in pairs may, but need not, be identical. This ultimately likewise depends on the specific construction and the application, as does the flow direction of electric current and thermal current through the construction.

An important role is accorded, then, to the contacts 4 and 5. The latter provide for a close connection between material and supply line. If the contacts are poor, then high losses occur here, which can severely restrict the performance of the component. For this reason, when in use, the legs and contacts are frequently also pressed onto the material. The contacts are thus subjected to heavy mechanical loading. This mechanical loading increases further as soon as elevated (or indeed reduced) temperatures and/or thermal cycling play a part. The thermal expansion of the materials incorporated in the component leads inevitably to mechanical stress, which leads in extreme cases to failure of the component as a result of detachment of the contact.

In order to prevent this, the contacts used must have a certain flexibility and spring properties so that such thermal stresses can be compensated.

In order to impart stability to the whole structure and to ensure the necessary, maximally uniform thermal coupling over all the legs, carrier plates are required. For this purpose, a ceramic is usually used, for example composed of oxides or nitrides such as Al₂O₃, SiO₂ or AlN. This additionally ensures electrical insulation and high-temperature stability.

This typical construction entails a number of disadvantages. The ceramic and the contacts can be mechanically loaded only to a limited extent. Mechanical and/or thermal stresses may easily lead to cracks or contact detachment, rendering the entire module unusable.

Furthermore, limits are also imposed on the conventional structure with regard to use, since only planar surfaces can ever be connected to the thermoelectric module. A close connection between the module surface and the heat source/heat sink is indispensable for ensuring sufficient heat flow.

Non-planar surfaces, such as a round waste heat pipe, for example, are not amenable to direct contact with the conventional module, or require a corresponding straightened heat exchanger construction in order to provide a transition from the non-planar surface to the planar module.

Conventionally, a plurality of thermoelectric modules, as described above, which are mounted between a heat source and a heat sink and are electrically interconnected, form a thermoelectric generator.

The heat source is often an exhaust gas pipe, for example of an internal combustion engine. In this case, the thermoelectric generator must be in good thermal contact with the heat source, in order to ensure good heat transfer. To this end, the thermoelectric generator has to typically be pressed against the heat source. Here too this may lead to mechanical and/or thermal stresses, which may lead to cracks in the module.

The thermoelectric module and the entire thermoelectric generator are accordingly subjected to heavy mechanical loading. This mechanical loading increases as soon as major temperature differences and/or thermal cycling are added. The thermal expansion of the materials incorporated in the component leads inevitably to mechanical stresses, which may lead in extreme cases to failure of the component.

In order to prevent this, the thermoelectric module must overall also have a certain flexibility and spring properties so that such thermal stresses can be compensated. The same is true of the entire thermoelectric generator.

Electrical contacting of the modules may be resilient or buffering, copper pads or copper nonwovens being usable for contacting purposes, for example. The metal nonwoven exhibits greater flexibility than a solid metal piece, due to the porosity of the nonwoven structure, but also lower thermal conductivity and hence less heat flow in the module. Alternatively, springs may be provided for compensating thermal stresses.

DE-A-10 2005 005 077 relates to a thermoelectric generator for an internal combustion engine. Individual thermoelectric modules are pressed herein against the exhaust gas line with the assistance of a Belleville spring and a washer, cf. FIG. 5 of said document. In this way, each thermoelectric generator element is held in a state in which it is pressed between the cooling portion and the sleeve. The thermoelectric generator elements arranged around the exhaust gas line are additionally joined together and to the exhaust gas line by way of a clip.

U.S. Pat. No. 5,450,869 relates to a heating mechanism, which includes a light, compact thermoelectric converter. The individual thermoelectric generators are pressed against a heat source by means of spiral springs.

DE-A-10 2007 063 173 relates to a thermoelectric generator which comprises thermoelectric modules joined to an exhaust gas line via metal plates, clamps and screwed joints. This results in increased weight and considerable complexity in terms of apparatus.

For good heat transfer between heat source and thermoelectric module, firmly bonded joints or elevated contact pressures are needed between the components of the thermoelectric module and the heat source or heat sink.

It is an object of the present invention to provide a thermoelectric generator which ensures good contact between the thermoelectric module contained therein and the heat source and heat sink.

The object is achieved according to the invention by a thermoelectric generator, which comprises at least one thermoelectric module between a hot side, which is connected to a heat source, and a cold side, which is connected to a heat sink, wherein a membrane rests against the cold side of the thermoelectric module, on which membrane a hydraulic pressure is exerted via a pressurized heat transfer fluid lying against the other side of the membrane, with which pressure the thermoelectric module is pressed against the hot side of the thermoelectric generator. Alternatively or in addition, the membrane may also rest against the hot side of the thermoelectric module. The heat transfer fluid may accordingly constitute the heat sink or heat source.

The object is additionally achieved by a thermoelectric generator unit comprising a plurality of thermoelectric generators substantially uniformly spaced around an exhaust gas line, preferably of an internal combustion engine, an outer edge enclosing the exhaust gas line and the thermoelectric generators.

The thermoelectric generator according to the invention allows flexible installation of the thermoelectric module when in service and improved heat flow thanks to optimized thermal coupling. The thermoelectric generator allows the transfer surfaces of the hot and cold sides of the module to be pressed with elevated pressure onto the planar module faces, such that good heat or cold transfer is possible at the module and also electrical and thermal resistances are minimized in the module itself.

Typically the waste heat from the exhaust gas stream of an internal combustion engine or of an internal combustion engine of a motor vehicle is used as the hot side. Cooling in the form of a cooling liquid from the engine cooling circuit may in this case constitute the cold side. The complete thermoelectric generator unit should in this case be capable of installation straightforwardly and space-savingly in a motor vehicle exhaust gas line. This is possible with the thermoelectric generator according to the invention.

In the thermoelectric generator according to the invention the hot side is connected to a heat source. The term “connected” indicates a spatial connection which allows maximum heat transfer. If the heat source is an exhaust gas pipe, for example, the connection is produced for example by the thermoelectric generator being pressed onto the exhaust gas pipe or by a mechanical connection of the thermoelectric generator to the exhaust gas pipe, the largest possible contact surface being provided, to allow particularly good heat transfer.

The cold side of the thermoelectric generator is in this case connected to a heat sink, for example the engine cooling circuit or ambient air. The term “connected” here has the same meaning as above and indicates a spatial connection which results in the greatest possible heat transfer. The thermoelectric generator may be pressed with its cold side against the heat sink or connected mechanically thereto.

Often, the contacts are merely laid on and pressed against the hot side of the thermoelectric generator, while they are firmly connected to the cold side.

The cooling liquid, which flows in heat-conducting contact through the membrane housing, may constitute the heat sink. The heat transfer fluid is here just a heat transfer medium which transports the heat from the cold side of the thermoelectric module to the cooling liquid acting as a heat sink.

### General Description of the Membrane Principle

At least one thermoelectric module, as described above, is arranged in the thermoelectric generator, between a hot side and a cold side. A membrane, on which a pressure is exerted, rests against the cold side of the thermoelectric module. With this pressure, the membrane presses the thermoelectric module against the hot side of the thermoelectric generator, for example against an exhaust gas line. The pressure in the form of a hydraulic pressure from a heat transfer fluid resting on the membrane is exerted on the membrane. While the cold side of the thermoelectric module rests against the one side of the membrane, the heat transfer fluid rests against the other side of the membrane. If a hydraulic pressure is exerted on the heat transfer fluid, said pressure is transmitted via the membrane to the cold side of the thermoelectric module and presses the latter against the hot side, which is connected to a heat source.

The pressure chamber may be vented for example via a vent plug, similar to an embodiment known from motor vehicle brakes.

The term “membrane” denotes a material which is stable, firm and flexible at service temperatures, which is impermeable to the heat transfer fluid, which is stable under pressure but is deformable and is capable of compensating slight unevennesses when pressed against the thermoelectric module. Any desired suitable membrane materials may be used. The membrane is preferably a metal membrane, the metal preferably having a thickness in the range from 10 to 1000 μm. The membrane is particularly preferably made from mechanically stable metals or the alloys thereof.

### Description of Variant 1

Pressure on the membrane produced with fluid and pressure screw, cooling action by cooling liquid

So that a hydraulic pressure can be exerted on the membrane via the pressurized heat transfer fluid, the heat transfer fluid is located in a receptacle closed on all sides, one side of which is formed by the membrane. At least one point, it must be possible to introduce a hydraulic pressure into the heat transfer fluid contained in this receptacle.

According to one embodiment of the invention the heat transfer fluid itself constitutes the heat sink. It is then possible to produce sufficient pressure for contact pressure purposes in the heat transfer fluid by means of a pressure intensifier. For example the engine cooling circuit of an internal combustion engine may be used directly as heat transfer fluid. Since the engine cooling circuit is under only slight pressure, some of the engine coolant must typically be branched off from the circuit and exposed to pressure. This may preferably proceed with the assistance of a pressure intensifier, which generates sufficient pressure for contact pressure purposes in the heat transfer fluid.

An embodiment is preferred here in which the heat transfer fluid is a cooling liquid, which flows along the membrane or through the membrane block.

In this embodiment the heat transfer fluid may thus consist of a hydraulic fluid, the cooling liquid then flowing through the membrane block.

The flow velocity is in this case adjusted such that sufficient heat is removed from the cold side of the thermoelectric module.

If the thermoelectric generator is installed in the exhaust gas stream of a motor vehicle internal combustion engine, the hot side of the thermoelectric generator must rest against the exhaust gas pipe, while cooling proceeds with cooling liquid from the engine cooling circuit. It should then be possible to fit the complete unit straightforwardly and space-savingly in an exhaust gas pipe of a vehicle, wherein it is brought into contact with the exhaust gas pipe and the engine cooling circuit with sufficiently high pressure to ensure ideal heat transfer. This optimized thermal coupling is one of the aims of the present invention. It is also intended that maximally flexible installation of the generator be possible when in use, so as to be able to adapt the generator to the widest possible variety of types of engines and exhaust gas systems.

According to a first design variant, the thermoelectric generator or the thermoelectric module is clamped by means of a thermally insulated flanged ring between a base member with heat transfer ribs, which constitutes the hot side, and a pressure plate on the cold side. Alternatively, connection may be effected with electrically and thermally insulated screws.

The pressure plate here preferably consists of a welded-on, thin metal membrane, a pressure chamber, which is filled with a heat-resistant fluid (for instance a gas or a liquid or supercritical medium), and a pressure screw. The entire pressure plate in this case preferably contains bores, through which the engine cooling water is passed for cooling purposes.

A corresponding embodiment of the invention is shown in FIG. 3, in which the following definitions apply:

A hot side
B cold side
C cooling water return
D thermal insulation
E oil at a pressure of 69 bar (1000 psi)
F cooling water intake, typically at a temperature of 80 to 90° C., 360 to 500 kg/h
G exhaust gas pipe
H hot exhaust gas, temperature typically 550° C., 144 kg/h

If the pressure screw is tightened, it exerts a force on the fluid via the end face. The fluid transmits this pressure hydraulically to the membrane. In this way a uniform pressure is applied to the, preferably planar, surface of the thermoelectric module. This uniform contact pressure ensures that on the hot side the base member and on the cold side the pressure plate are pressed on homogeneously and adjustably.

The pressure chamber may be vented for example via a vent plug, similar to an embodiment known from motor vehicle brakes.

The complete unit may then be fitted into the engine's exhaust gas line.

### Description of Variant 2

Pressure on the membrane produced with engine cooling liquid and pressure intensifier, cooling action by cooling liquid

Instead of a pressure screw, the hydraulic pressure may also be transferred to the heat transfer fluid via a pressure plate or a pressure piston. This embodiment is of particular interest if the heat transfer fluid is in heat-conducting contact with the heat sink.

An embodiment is preferred here in which the heat transfer fluid is a cooling liquid, which flows through the membrane block.

The flow velocity is in this case adjusted such that sufficient heat is removed from the cold side of the thermoelectric module.

According to one embodiment of the invention the heat transfer fluid itself constitutes the heat sink. It is then possible to produce sufficient pressure for contact pressure purposes in the heat transfer fluid by means of a pressure intensifier. For example the engine cooling circuit of an internal combustion engine may be used directly as heat transfer fluid. Since the engine cooling circuit is under only slight pressure, some of the engine coolant must typically be branched off from the circuit and its pressure increased. This may preferably proceed with the assistance of a pressure intensifier, which generates sufficient pressure for contact pressure purposes in the heat transfer fluid.

The available 1 bar cooling water pressure is then increased to pressures for example in the range from 50 to 100 bar, preferably 60 to 75 bar, in particular 65 to 73 bar. This increased pressure is used to act on the membrane and generate the desired contact pressure on the planar faces of the module.

In this embodiment the cooling liquid may thus constitute the heat transfer fluid, which flows along the membrane along or through the membrane block.

Alternatively, a cooling liquid which flows in heat-conducting contact along the heat transfer fluid may constitute the heat sink. The heat transfer fluid is here just a heat transfer medium which transports the heat from the cold side of the thermoelectric module to the cooling liquid acting as a heat sink. The cooling liquid, which flows over the membrane block in heat-conducting contact with the heat transfer fluid, may thus constitute the heat sink.

The pressure intensifier, which generates sufficient pressure in the heat transfer fluid to press the membrane against the thermoelectric module or to press the thermoelectric module against the contacts of the hot side, may take any desired suitable form. A suitable design is shown in FIG. 4. Pressure intensification proceeds with the same applied force by reducing the surface area exposed to the force.

In FIG. 4 A means the inflowing cooling water circuit with a pressure of approx. 1 bar and B the intensified pressure of approx. 69 bar.

When the pressure intensifier is in the starting position, the piston is maintained in the starting position by the spring force. The pressure chamber for the membrane then fills up with cooling water.

Once the internal combustion engine has started, the cooling water heats up, and the pressure in the cooling water increases to approx. 1 bar. The large piston face is then exposed to pressure, and the piston extends, until the first O-ring has passed over the transverse bore. The transverse bore is thus closed off.

The pressure on the small piston face then amounts, depending on the piston diameter ratio, to 69 bar and may expose the membrane to a hydraulic force.

If the engine is shut down the cooling water cools. The pressure thereby lessens, and the piston is brought back into the starting position by the spring force.

According to the second design variant the exhaust gas pipe in the exhaust gas unit takes the form of a polygonal pipe with ribs. The pipe preferably comprises at least three vertices. It may for example be a square pipe, a hexagonal pipe or an octagonal pipe. The embodiment with ribs produces a bending-resistant embodiment.

If a pipe of square cross section is used for example, a flanged joint can be dispensed with by the four-fold arrangement of the thermoelectric modules or thermoelectric generators around the circumference of the square pipe. Encasing the arranged modules in a pipe allows the modules to be held together as a whole unit.

This embodiment corresponds to a thermoelectric generator unit comprising a plurality of thermoelectric generators, as described above, substantially uniformly spaced around an exhaust gas line, preferably of an internal combustion engine, wherein an outer casing encloses the exhaust gas line and the thermoelectric generators.

The term “exhaust gas line” is used here in its broadest sense. It is preferably an exhaust gas pipe of an internal combustion engine. The exhaust gas pipe may be located up- or downstream of a silencer or exhaust gas catalyst. The thermoelectric generator unit is preferably located at a point in the exhaust gas line at which an elevated exhaust gas temperature prevails. Particular efficiency may be achieved for the thermoelectric module by a large temperature difference between the hot and cold sides.

The thermoelectric module integrated into the thermoelectric generator or into a heat exchanger has a number of advantages:

thermal and mechanical stresses may be simply compensated and relieved.

In this way non-planar heat sources or heat sinks are also amenable to close connection to the thermoelectric module.

No or only minimal mechanical or thermal stress is produced in the material and joints by the thermal expansion of the material.

Joints and contact points in the module and throughout the entire generator have minimized thermal resistance and electrical resistance due to the dynamic contact pressure.

The total weight of the thermoelectric generator is reduced by the construction according to the invention, since contact pressure by way of the membrane makes some of the otherwise necessary clamps, screwed joints and clips superfluous. In known devices, installation of the thermoelectric module in a generator often proceeds by way of metal plates, clamps and screwed joints for fixing and contact pressure purposes.

The heat transfer fluid, preferably the hydraulic fluid, may at the same time be used as a heat-transfer medium and heat reservoir. This ensures homogeneous heat distribution over a plurality of thermoelectric modules. In an exhaust gas line of an internal combustion engine there is a temperature gradient between engine and exhaust gas outlet. In this way, the thermoelectric materials used close to the engine may be thermoelectric materials for higher temperatures, which work more efficiently since they have a higher Carnot efficiency, while in parts of the exhaust gas line remote from the engine thermoelectric materials for lower temperatures are used. Better utilization of the waste heat is made possible by the better heat distribution of the medium by the double-walled design of the thermoelectric generator over the entire surface area of the generator and leads to increased generator efficiency.

In addition, the stored heat may also be transported more rapidly by the fluid to where it is needed when in use. For example, in an exhaust gas catalyst very rapid heating of the catalyst is desirable, to allow the catalyst to become immediately active even after a cold start.

In the start phase of an engine it takes a few minutes for the maximum temperature of the exhaust gas to be reached. In an automobile, for instance, it takes around 7 km of expressway driving for the exhaust gas line and the catalyst to be heated to the necessary temperature of approx. 700° C. In this period a thermoelectric generator integrated into the exhaust gas line will supply barely any energy. By using a medium as a heat reservoir, however, heat from a previous journey may still be used as residual heat if the engine has not been at a standstill for too long, thus shortening the start phase. The thermoelectric generator thus accordingly also produces electrical power sooner.

The thermoelectric generator is preferably made according to the invention with a double-walled jacket over the electrically contacted thermoelectric legs, which are electrically insulated from the jacket. The double wall is filled with a heat transfer fluid, which produces the necessary contact pressure on the thermoelectric modules.

The fluid may counteract the thermal stresses in the thermoelectric module by thermal expansion or contraction, such that mechanical stress in the thermoelectric module is relieved. As a result of its inherent pressure, the fluid may produce optimum thermal coupling and minimal thermal resistance between the thermoelectric module and the heat source or heat sink.

The fluid concept allows different geometric embodiments of the thermoelectric module and thermoelectric generator.

The fluid may be gaseous or liquid or a mixture thereof. Solids may also be contained in the fluid, such as aerogels or graphite. Possible gases which may be considered are air and inert gases. Liquids which may be considered are in particular water, heat-transfer oils such as organic oils and heat transfer salts such as inorganic salts or liquid metals.

The fluid allows volume control and may thus respond very flexibly to changes in volume in the event of temperature fluctuations.

The weight of the entire thermoelectric generator may be reduced by the module construction according to the invention consisting of membrane, pressure intensifier and thermoelectric module in the exhaust gas line, since contact pressure by way of the membrane allows some of the otherwise necessary mechanical clamps, screwed joints etc. to be omitted. The type of thermoelectric material in the thermoelectric module may be freely selected. For a description of suitable thermoelectric materials, reference may be made to the above-mentioned literature.

The respective thermoelectric module is here made up of p- and n-conductive thermoelectric material legs, which are connected to one another via electrically conductive contacts. The electrically conductive contacts here preferably comprise points of flexibility over their profile on the cold and/or hot side of the thermoelectric module between the thermoelectric material legs, which points allow bending and slight displacement of the thermoelectric material legs relative to one another.

The basic structure of the thermoelectric material legs is described above. For more details of the structure of the thermoelectric modules reference may additionally be made to U.S. Pat. No. 5,450,869, DE-A-10 2005 005 077 and DE-A-10 2007 063 173.

1. A thermoelectric generator, which comprises at least one thermoelectric module between a hot side, which is connected to a heat source, and a cold side, which is connected to a heat sink, wherein a membrane rests against the cold side of the thermoelectric module, on which membrane a hydraulic pressure is exerted via a pressurized heat transfer fluid lying against the other side of the membrane, with which pressure the thermoelectric module is pressed against the hot side of the thermoelectric generator, and/or wherein a corresponding membrane rests against the hot side of the thermoelectric module.

2. The thermoelectric generator as claimed in claim 1, wherein the heat transfer fluid constitutes the heat sink or heat source.

3. The thermoelectric generator as claimed in claim 2, wherein a pressure sufficient for contact pressure purposes is produced in the heat transfer fluid by means of a pressure intensifier.

4. The thermoelectric generator as claimed in claim 3, wherein the heat transfer fluid is a cooling liquid, which flows through the membrane block.

5. The thermoelectric generator as claimed in claim 1, wherein the heat transfer fluid is in heat-conducting contact with the heat sink.

6. The thermoelectric generator as claimed in claim 5, wherein the hydraulic pressure is transferred to the heat transfer fluid via a pressure plate, a pressure piston and/or a pressure screw.

7. The thermoelectric generator as claimed in claim 5, wherein a cooling liquid, which flows over the membrane block in heat-conducting contact with the heat transfer fluid, constitutes the heat sink or heat source.

8. The thermoelectric generator as claimed in claim 4, wherein the cooling liquid is part of a cooling water circuit, preferably of an internal combustion engine.

9. The thermoelectric generator as claimed in claim 1, wherein it is designed for installation in an exhaust gas line, preferably of an internal combustion engine.

10. A thermoelectric generator unit, which comprises a plurality of thermoelectric generators as claimed in claim 1 substantially uniformly spaced around an exhaust gas line, preferably of an internal combustion engine, wherein an outer casing encloses the exhaust gas line and the thermoelectric generators.
